(19) United States
(12) Patent Application Publication
(10) Pub. No.: US 2006/0157197 A1
(43) Pub. Date: Jul. 20, 2006

(54) Substrate processing apparatus

(76) Inventors: Tadashi Maegawa, Kyoto (JP); Nobuharu Nagara, Kyoto (JP)

Correspondence Address: OSTROLENK FABER GERB & SOFFEN, 1180 AVENUE OF THE AMERICAS, NEW YORK, NY, 100368403, US

(21) Appl. No.: 11/329,014

(22) Filed: Jan. 10, 2006

(30) Foreign Application Priority Data
Jan. 18, 2005 (JP) JP2005-009996
Jan. 28, 2005 (JP) JP2005-021371

(51) Int. Cl. H01L 21/306; C23F 1/00

(52) U.S. Cl. 156/345.18; 156/345.13

(57) ABSTRACT

In liquid exchange processing for exchanging a processing liquid retained in a processing bath from pure water to sulfuric acid and controlling the exchanged sulfuric acid at a predetermined temperature, firstly, pure water is discharged from the processing bath and an external bath. Then, sulfuric acid is supplied from a supply nozzle into the external bath. Then, timing to start circulation processing for circulating sulfuric acid from the external bath to the processing bath, and timing to start temperature control of the processing liquid are determined according to the amount of sulfuric acid retained in the external bath, which amount is obtained from a detection result by a pressure sensor. Accordingly, the temperature control can be started before the supply from the supply nozzle is completed. This shortens the time required for the liquid exchange processing.

### BACKGROUND OF THE INVENTION

1. Field of the Invention

The present invention relates to a substrate processing apparatus for performing predetermined processing on substrates such as semiconductor substrates, glass substrates for liquid crystal displays or for photomasks, and optical disk substrates, by immersing those substrates in pure water or chemical solutions (hereinafter generically referred to as processing liquids) retained in a processing bath. And, the present invention especially relates to improvement in the procedure for exchange of a processing liquid retained in a processing bath.

2. Description of the Background Art

There are conventionally known substrate processing apparatuses for performing predetermined processing on substrates by immersing those substrates in a processing liquid retained in a processing bath.

Now, conventional liquid exchange processing for exchanging a processing liquid retained in a substrate processing bath in a substrate processing apparatus and controlling the exchanged processing liquid at an appropriate temperature for substrate processing is performed using the following procedure.

Specifically, in the conventional liquid exchange processing, firstly, processing liquids in a substrate processing bath and in an overflowing-liquid collection unit are discharged in this order to the outside of the apparatus (first and second steps). Then, after completion of the discharge of processing liquids from the substrate processing bath and from the overflowing-liquid collection unit, a new processing liquid is supplied into the substrate processing bath (third step). After the processing liquid supplied into the substrate processing bath overflows and is collected in the overflowing-liquid collection unit, circulation processing for resupplying a processing liquid from the overflowing-liquid collection unit into the substrate processing bath is started (fourth step). After the start of the circulation processing, a thermoregulator starts its operation to control the temperature of the processing liquid (fifth step). The liquid exchange processing is completed at a time when a predetermined amount of a processing liquid in the substrate processing bath is maintained at a predetermined temperature, and substrate processing using the exchanged processing liquid becomes possible. In this way, the conventional liquid exchange processing has required sequential execution of the above first to fifth steps.

However, for further improvement in throughput in substrate processing, a time required for the liquid exchanging processing becomes an issue. Also, for example in the case where a processing liquid of approximately room temperature that is not preheated is supplied into the substrate processing bath, a time required to control the processing liquid at a predetermined temperature becomes an issue as well.

### SUMMARY OF THE INVENTION

The present invention is directed to a substrate processing apparatus for processing substrates.

According to an aspect of the present invention, the substrate processing apparatus includes a processing bath retaining a processing liquid; an external bath provided outside the processing liquid to collect a processing liquid overflowing from the processing bath; a pipe communicating and connecting the external bath and the processing bath; a thermoregulator provided on the pipe to control a temperature of a processing liquid flowing through the pipe; a circulator provided on the pipe to supply a processing liquid discharged from the external bath through the pipe into the processing bath; a sensor detecting the amount of a processing liquid retained in the external bath; and a controller supplying a processing liquid discharged from the external bath through the pipe into the processing bath using the circulator when the sensor detects a first value of the amount of a processing liquid retained in the external bath, and actuating the thermoregulator when the sensor detects a second value of the amount of the processing liquid that is greater than the first value.

Since the circulation of a processing liquid by the circulator and the temperature control of the circulating processing liquid can be started before the supply of processing liquid is completed, throughput in substrate processing can be improved.

Preferably, the processing liquid includes a first processing liquid and a second processing liquid. The substrate processing apparatus further includes a first discharge pipe connected to the processing bath to discharge a first processing liquid retained in the processing bath; and a second discharge pipe connected to the pipe to discharge a first processing liquid retained in the external bath through the pipe. The processing-liquid supplier supplies a second processing liquid after a first processing liquid is discharged from the first and second discharge pipes.

This shortens the time required to exchange the first processing liquid for the second processing liquid.

According to another aspect of the present invention, the substrate processing apparatus includes: a processing bath retaining a processing liquid; a first supplier supplying a processing liquid into the processing bath; an external bath provided outside the processing bath to collect a processing liquid overflowing from the processing bath; a first discharge pipe discharging a processing liquid retained in the processing bath; a first valve provided on the first discharge pipe; a second discharge pipe discharging a processing liquid retained in the external bath; a second valve provided on the second discharge pipe; a common discharge pipe connected to the first and second discharge pipes to discharge a processing liquid discharged through the first and second discharge pipes; a second supplier supplying a processing liquid discharged through the first and second discharge pipes into the processing bath; a supply pipe connected to the common discharge pipe and the second supplier; a third valve provided on the supply pipe; a thermoregulator provided on the supply pipe to control a temperature of a processing liquid circulating through the supply pipe; a fourth valve provided on the common discharge pipe and downstream of a point where the supply pipe is connected; and a controller controlling the supply of a processing liquid from the first supplier and opening and closing of the first to fourth valves. The controller opens the first, third, and fourth valves to discharge a first processing liquid retained in the processing bath through the first discharge pipe and the common discharge pipe and to discharge a first processing liquid remaining in the supply pipe through the supply pipe and the common discharge pipe. The controller, while causing the first supplier to supply a second processing liquid into the processing bath, opens the second valve to discharge a first processing liquid retained in the external bath through the second discharge pipe and the common discharge pipe. The controller, while causing the first supplier to supply a second processing liquid into the processing bath, opens the first and third valves to perform first circulation processing for circulating a second processing liquid retained in the processing bath from the second supplier to the processing bath through the first discharge pipe, the common discharge pipe, and the supply pipe. The controller stops the first circulation processing according to the amount of a second processing liquid collected in the external bath, and while causing the first supplier to supply a second processing liquid into the processing bath, opens the second and third valves to perform second circulation processing for circulating a second processing liquid collected in the external bath from the second supplier to the processing bath through the second discharge pipe, the common discharge pipe, and the supply pipe.

This shortens the time required to exchange the first processing liquid for the second processing liquid that is temperature-controlled and thus further improves throughput in substrate processing.

Accordingly, it is an object of the present invention to provide a substrate processing apparatus that is capable of further improving throughput in substrate processing which is performed by immersing substrates in a processing liquid retained in a processing bath.

These and other objects, features, aspects and advantages of the present invention will become more apparent from the following detailed description of the present invention when taken in conjunction with the accompanying drawings.

### BRIEF DESCRIPTION OF THE DRAWINGS

FIG. 1 shows an example of the configuration of a substrate processing apparatus according to a first preferred embodiment of the present invention;

FIG. 2 is a timing chart for explaining liquid exchange processing of processing liquids according to the first and a second preferred embodiments;

FIG. 3 is a diagram for explaining timing to start circulation processing and temperature control according to the first preferred embodiment;

FIG. 4 shows an example of the configuration of a substrate processing apparatus according to the second preferred embodiment of the present invention;

FIG. 5 is a diagram for explaining timing to start circulation processing and temperature control according to the second preferred embodiment;

FIG. 6 shows an example of the configuration of a substrate processing apparatus according to a third preferred embodiment of the present invention;

FIG. 7 is a timing chart for explaining liquid exchange processing of processing liquids according to the third preferred embodiment;

FIGS. 8 to 12 are diagrams for explaining passages of processing liquids in the liquid exchange processing according to the third preferred embodiment; and

FIG. 13 is a timing chart for explaining conventional liquid exchange processing.

### DESCRIPTION OF THE PREFERRED EMBODIMENTS

Hereinbelow, preferred embodiments of the present invention will be described with reference to the drawings.

### 1. First Preferred Embodiment

<1.1 Configuration of Substrate Processing Apparatus>

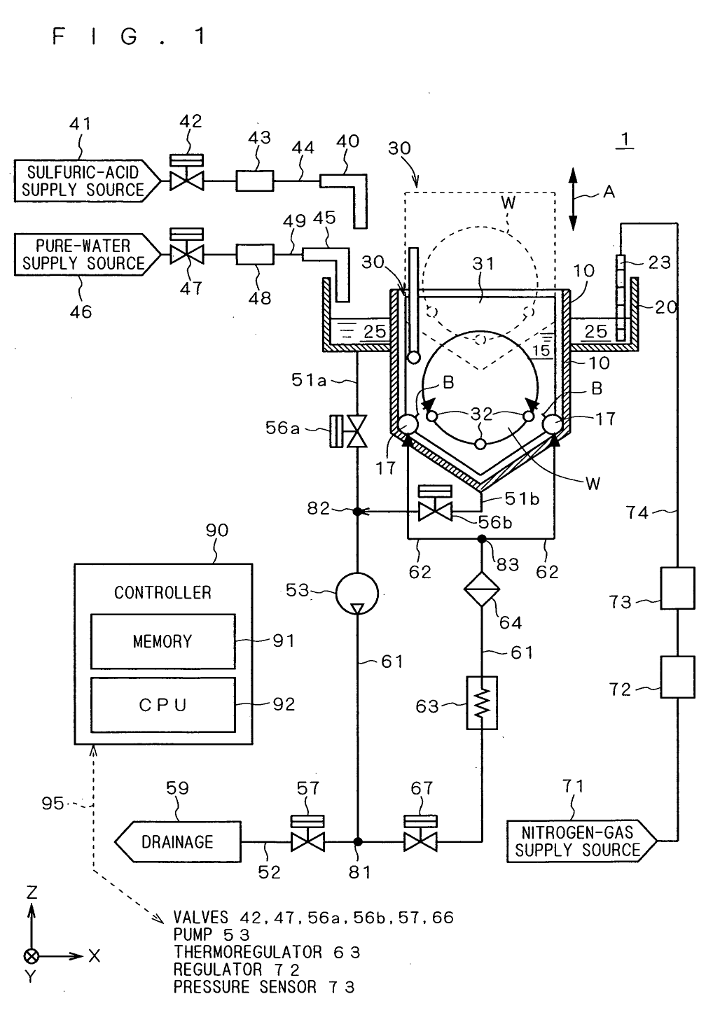

FIG. 1 shows an example of the configuration of a substrate processing apparatus 1 according to a first preferred embodiment of the present invention. The substrate processing apparatus 1 is a so-called “batch” substrate processing apparatus for processing a plurality of substrates at a time. As shown in FIG. 1, the substrate processing apparatus 1 mainly includes a processing bath (internal bath) 10, an external bath 20 provided outside the processing bath 10 in order to collect a processing liquid overflowing from the processing bath 10, and pipes 51a, 61, and 62 for resupplying a processing liquid discharged from the external bath 20 into the processing bath 10.

The processing bath 10 retains therein a processing liquid 15, in which a plurality of substrates W are immersed for processing such as cleaning and etching. Further, two processing-liquid nozzles 17 extending in the Y axis direction are provided inside and near the bottom of the processing bath 10, and a processing liquid discharged from the external bath 20 is supplied through the pipes 51a, 61, and 62 and from the processing-liquid nozzles 17 into the processing bath 10 as indicated by the arrows B.

An elevation mechanism 30 is a mechanism for immersing a plurality of substrates W in a processing liquid retained in the processing bath 10 and, as shown in FIG. 1, mainly includes a lifter 31 and holding bars 32. The lifter 31, as indicated by the arrow A, is moved up and down between positions above and within the processing bath 10 in the Z axis direction by a drive mechanism (not shown). The lifter 31 has the three holding bars 32 attached thereto and extending along the Y axis direction. The three holding bars 32 each have a plurality of holding grooves (not shown) engraved thereon, and the substrates W are held in upright positions with their outer edges being inserted in the corresponding holding grooves.

Thus, the plurality of substrates W held by the three holding bars 32 are moved up and down by the lifter 31 between their positions immersed in the processing liquid 15 and their positions above the processing bath 10 to be delivered to a carrier robot (not shown).

On the outer top part of the processing bath 10, as shown in FIG. 1, the external bath 20 is provided to surround the outer edge of the processing bath 10. Thus, a processing liquid overflowing from the processing bath 10 is collected in the external bath 20.

Above the external bath 20, supply nozzles 40 and 45 are provided. As shown in FIG. 1, the supply nozzle 40 is communicated and connected to a sulfuric-acid supply source 41 via a valve 42, a flowmeter 43, and a pipe 44. The supply nozzle 45 is communicated and connected to a pure-water supply source 46 via a valve 47, a flowmeter 48, and a pipe 49. By controlling on and off of the valves 42 and 47, the supply nozzles 40 and 45 supply sulfuric acid and pure water, respectively, into the external bath 20 from above.

The flowmeters 43 and 48, as shown in FIG. 1, are provided on the pipes 44 and 49, respectively, and measure the flow rates of sulfuric acid supplied from the sulfuric-acid supply source 41 and pure water supplied from the pure-water supply source 46 per unit time, respectively. On the basis of detection values of those flowmeters 43 and 48, the amounts of sulfuric acid and pure water supplied into the external bath 20 are determined.

The external bath 20 also has provided therein a gas discharger (level sensor) 23 for discharging nitrogen gas in a processing liquid retained in the external bath 20. This gas discharger 23 is connected through a pipe 74 to a nitrogen-gas supply source 71. This pipe 74 is provided with a regulator 72 and a pressure sensor 73 when viewed from the upstream. The regulator 72 controls the flow rate of nitrogen gas supplied from the nitrogen-gas supply source 71 per unit time at a certain value. The pressure sensor 73 detects the pressure of nitrogen gas flowing through the pipe 74.

For detection of the amount of a processing liquid retained in the external bath 20, firstly, the regulator 72 controls the flow rate of nitrogen gas supplied from the nitrogen-gas supply source 71 at a certain value, and nitrogen gas is supplied through the pipe 74 and from the gas discharger 23 in the processing liquid retained in the external bath 20. At this time, the pressure sensor 73 detects the pressure value corresponding to the amount of a processing liquid retained in the external bath 20. This pressure value increases with increasing amount of retained processing liquid.

Inside the external bath 20 is communicated and connected to the pipe 51a. The pipe 51a has an openable valve 56a provided thereon. The pipe 51a is also connected to a common pipe 61 at a communication point 82. Further, the pipe 51a is also connected at the communication point 82 to a first discharge pipe 51b which is connected to the inside of the processing bath 10 and on which an openable valve 56b is provided.

The common pipe 61 is a pipe for mainly supplying a processing liquid 25 discharged from the external bath 20 toward the processing bath 10. As shown in FIG. 1, the common pipe 61 has provided thereon a pump 53, a valve 66, a thermoregulator 63, and a filter 64 in order from the external bath 20 side to the processing bath 10 side. The common pipe 61 is also communicated and connected to two supply pipes 62 at a point 83. The two supply pipes 62 each are connected to a corresponding one of the processing-liquid nozzles 17.

Driving the pump 53 as well as opening the valves 56a and 66 and closing the valves 56b and 57 cause the processing liquid 25 collected in or supplied into the external bath 20 to be discharged in directions indicated by the arrows B through the pipe 51a, the common pipe 61, the thermoregulator 63, the supply pipes 62, and the processing-liquid nozzles 17 and to be supplied into the processing bath 10. In this way, the pump 53 circulates the processing liquid 25 retained in the external bath 20 through the pipe 51a, the common pipe 61, and the supply pipes 62 to the processing bath 10.

A second discharge pipe 52 is connected at its one end to a point 81 between the pump 53 and the valve 66 on the pipe 61. The other end of the second discharge pipe 52 is connected to a drainage 59. This second discharge pipe 52 is provided with an openable valve 57. The drainage 59 is provided outside the substrate processing apparatus 1 and used as a common facility in a semiconductor factory.

In order to discharge the processing liquid 25 retained in the external bath 20 as a drain, the pump 53 is driven, the valves 56a and 57 are opened, and the valves 56b and 66 are closed so that the processing liquid 25 collected in the external bath 20 is discharged through the pipe 51a, the common pipe 61, and the second discharge pipe 52 to the drainage 59. In order to discharge the processing liquid 15 retained in the processing bath 10 as a drain, the pump 53 is driven, the valves 56b and 57 are opened, and the valves 56a and 66 are closed so that the processing liquid 15 retained in the processing bath 10 is discharged through the first discharge pipe 51b, the common pipe 61, and the second discharge pipe 52 to the drainage 59. Further, when the valves 66 and 57 are opened and the valves 56a and 56b are closed, processing liquids remaining in the pipe 51a, the common pipe 61, and the supply pipes 62 are discharged under their own weights to the drainage 59.

The thermoregulator 63 provided on the common pipe 61 is for use in controlling the temperature of a processing liquid flowing through the common pipe 61 by techniques such as heating. The filter 64 is for use in removing particles or the like in a processing liquid flowing through the common pipe 61.

A controller 90, as shown in FIG. 1, includes a memory 91 that stores programs, variables, and the like, and a CPU 92 that exercises control according to programs stored in the memory 91. Further, the controller 90 is electrically connected through a signal line 95 to the valves 42, 47, 56a, 56b, 57, and 66, the pump 53, the thermoregulator 63, the regulator 72, the pressure sensor 73, and the like, for their control.

Thus, the CPU 92 performs control of the opening and closing of the valves 42, 47, 56a, 56b, 57, and 66, control of the driving of the pump 53, the thermoregulator 63, and the regulator 72, and other control with predetermined timing according to programs stored in the memory 91

<1.2. Procedure of Liquid Exchange Processing>

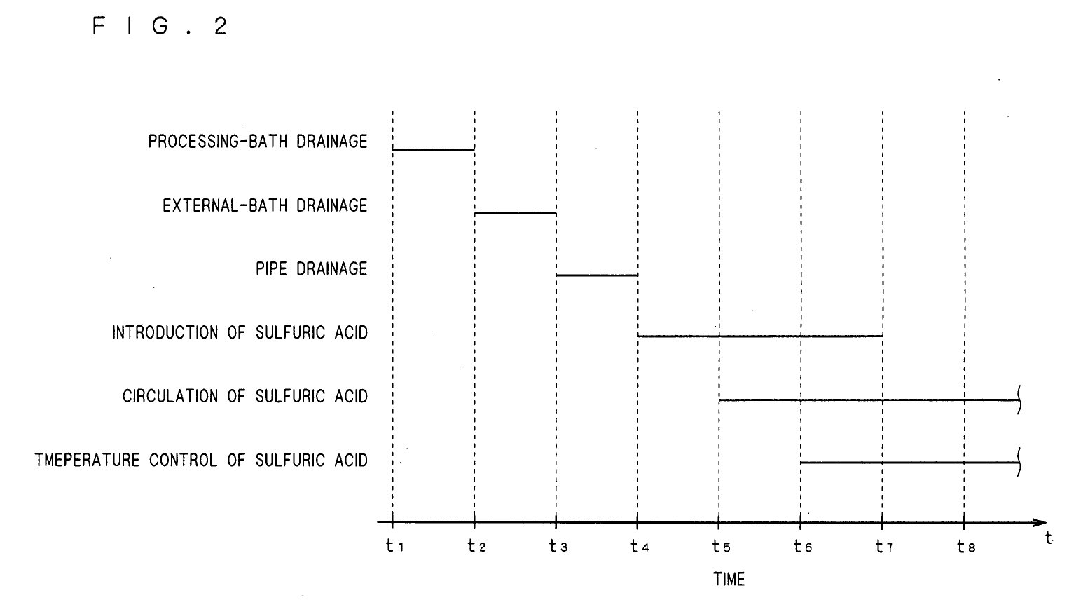

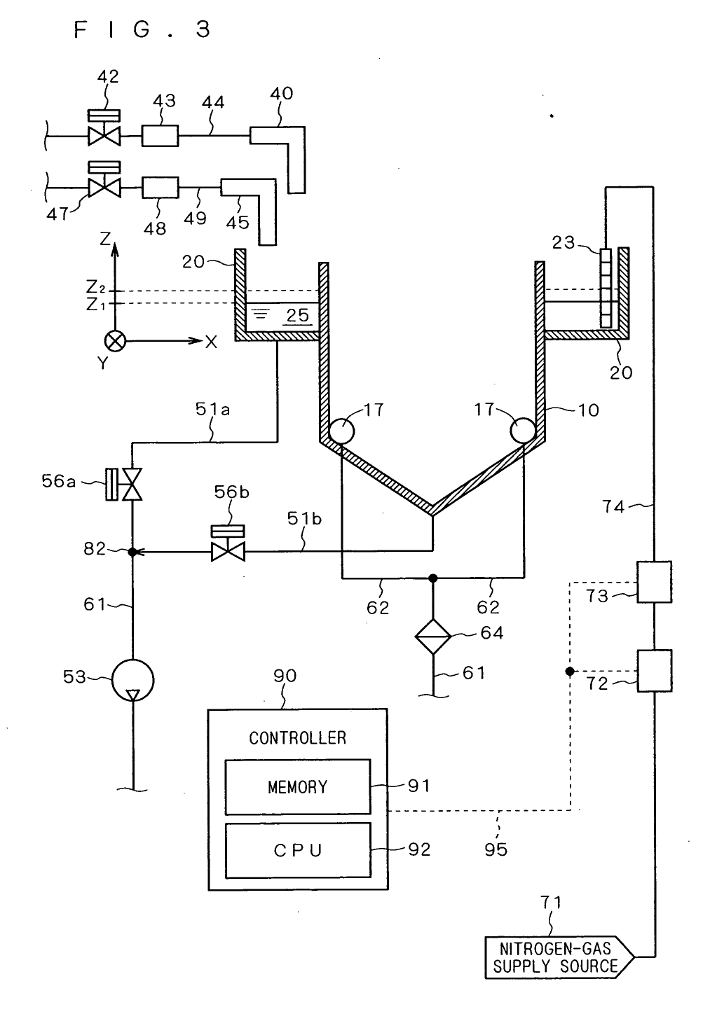

FIG. 2 is a timing chart for explaining processing-liquid exchange processing according to this preferred embodiment. FIG. 3 is a diagram for explaining timing to start circulation processing and timing to start temperature control by the thermoregulator 63. Now, the procedure of the liquid exchange processing will be described with reference to FIGS. 1 to 3.

The following description is about the processing of exchanging pure water (H₂O) as a first processing liquid, which has been retained in the processing bath 10 before time t₁, for sulfuric acid (H₂SO₄) as a second processing liquid. Before time t₁ in FIG. 2, the substrates W shall be moved up by the elevation mechanism 30 in the positive Z axis direction and delivered to a carrier robot (not shown). Further, sulfuric acid supplied into the external bath 20 shall be of approximately room temperature.

First, at time t₁, the pump 53 starts its operation, the valves 56b and 57 are opened, and the valves 56a and 66 are closed. This causes the pure water 15 retained in the processing bath 10 to be discharged by the drive of the pump 53 through the first discharge pipe 51b, the common pipe 61, and the second discharge pipe 52 to the drainage 59 (processing-bath drainage)

Then, at time t₂, with the pump 53 remaining in operation, the valve 56b is closed and the valve 56a is opened. This causes the pure water 25 collected in the external bath 20 to be discharged by drive of the pump 53 through the pipe 51a, the common pipe 61, and the second discharge pipe 52 to the drainage 59 (external-bath drainage).

Then, at time t₃, with the valve 57 remaining open, the pump 53 stops its operation, the valves 56a and 56b are closed, and the valve 66 is opened. This causes pure water remaining in the pipes 62 to be discharged under its own weight through the common pipe 61 and the second discharge pipe 52 to the drainage 59 (pipe drainage).

Then, at time t₄, at least with the valves 56a and 56b being closed, the valve 42 is opened so that sulfuric acid in the sulfuric-acid supply source 41 is supplied through the pipe 44 and from the supply nozzle 40 into the external bath 20 in which the sulfuric acid is retained. The supply of sulfuric acid continues until time t₇ when the necessary amount of supply for substrate processing is completed.

Then, at time t₅ when it is determined from a detection value of the pressure sensor 73 that the level Z and the amount V of the sulfuric acid 25 retained in the external bath 20 reach Z1 (indicated by solid lines in FIG. 3) and V1, respectively, the valves 56a and 66 are opened and the pump 53 is put into operation with the valves 56b and 57 being closed. This causes the sulfuric acid 25 retained in the external bath 20 to be supplied through the pipe 51a, the common pipe 61, and the two supply pipes 62 and from the processing-liquid nozzles 17 into the processing bath 10. That is, circulation processing for circulating the sulfuric acid 25 from the external bath 20 to the processing bath 10 is started at time t₅.

Here, as shown in FIG. 2, the valve 42 remains open even after the start of the circulation processing so that the supply nozzle 40 can continue to supply sulfuric acid into the external bath 20. Thus, the processing bath 10 continues to be supplied with and retain sulfuric acid discharged from the external bath 20. The amount V1 of the sulfuric acid 25 to be retained, which is used as a trigger to start the circulation processing, is predetermined through experiments or the like.

Then, at time t₆ when it is determined from the detection value of the pressure sensor 73 that the level Z and the amount V of the sulfuric acid 25 retained in the external bath 20 reach Z2 (indicated by broken lines in FIG. 3) and V2, respectively, the thermoregulator 63 starts its operation with the circulation of sulfuric acid being continued. This is the start of temperature control by the thermoregulator 63 to increase the temperature of sulfuric acid circulating through the common pipe 61.

Also in this case, the valve 42 remains open even after the start of the temperature control so that the processing bath 10 continues to be supplied with sulfuric acid. Then, when the amount of sulfuric acid discharged from the external bath 20 and supplied into the processing bath 10 exceeds the maximum amount of storage in the processing bath 10, the excess amount of sulfuric acid overflows from the processing bath 10 and is collected in the external bath 20.

In this way, the substrate processing apparatus 1 according to this preferred embodiment can start the temperature control while circulating sulfuric acid, at time t₆, i.e., before time t₇ when the supply of sulfuric acid is completed. Further, depending on the location of the thermoregulator 63, the temperature control can be started at a time before the processing bath 10 starts to retain the sulfuric acid 25. Thus, as compared with conventional substrate processing apparatuses, the substrate processing apparatus 1 can speed up the start time of the temperature control and thus can shorten the time required for the liquid exchange processing. The reason why the temperature control is started after the start of the circulation processing is to prevent the thermoregulator 63 from being damaged due to heating of an empty bath.

Then, the liquid exchange processing is completed at time t₈ when the temperature of the sulfuric acid 15 retained in the processing bath 10 is increased to a temperature at which substrate processing becomes possible (e.g., approximately 120° C.) by continuing the execution of the circulation processing.

Even after time t₈ when the substrate processing is started after the completion of the liquid exchange processing, the circulation processing is continued to be executed. Thus, sulfuric acid overflowing from the processing bath 10 is collected in and discharged from the external bath 20, and thermal energy is transmitted from the thermoregulator 63 provided on the common pipe 61 to the sulfuric acid. This allows the sulfuric acid to be maintained at a predetermined temperature.

<1.3. Advantages of Substrate Processing Apparatus of First Preferred Embodiment>

As so far described, the substrate processing apparatus 1 according to the first preferred embodiment can start the circulation of sulfuric acid at time t₅, i.e., before time t₇ when the supply of sulfuric acid is completed, and can start the temperature control of sulfuric acid circulating through the common pipe 61 at time t₆. This can speed up the start time of the temperature control and thus can shorten the time required for the liquid exchange processing.

### 2. Second Preferred Embodiment

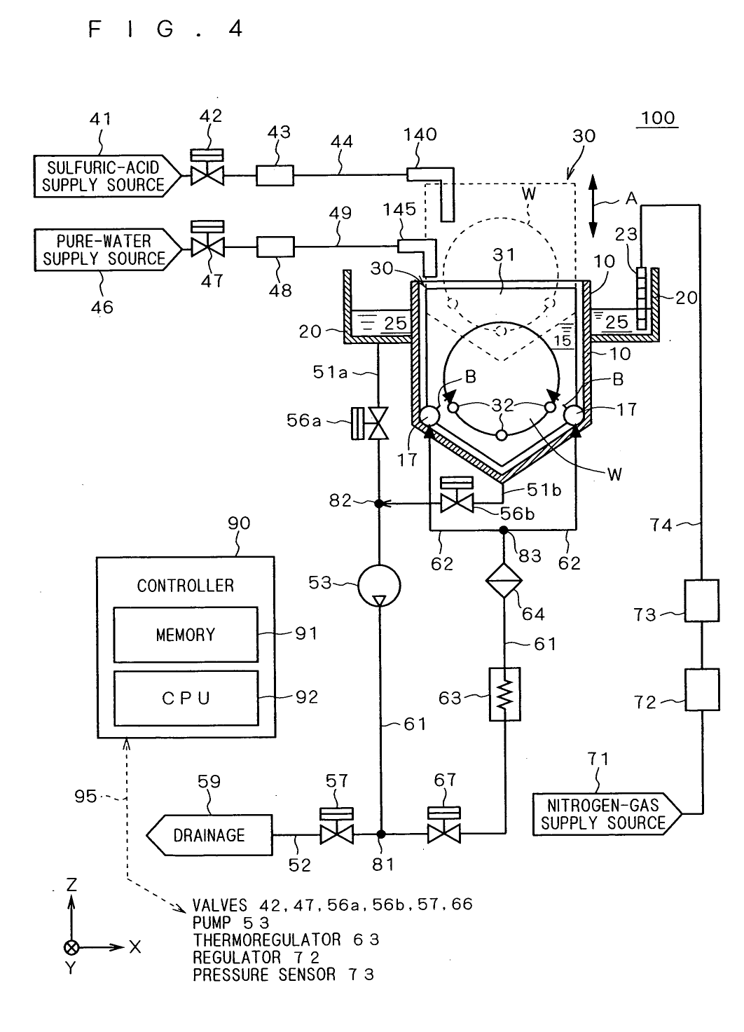

Next, a second preferred embodiment of the present invention will be described. FIG. 4 shows an example of the configuration of a substrate processing apparatus 100 according to this preferred embodiment. As shown in FIG. 4, the hardware structure of the substrate processing apparatus 100 according to this preferred embodiment differs from that of the substrate processing apparatus 1 of the first preferred embodiment, in that a sulfuric-acid supply nozzle 140 and a pure-water supply nozzle 145 are located above the processing bath 10. Other than that, the substrate processing apparatus 100 is identical to the substrate processing apparatus 1 of the first preferred embodiment. In other words, in the second preferred embodiment, processing liquids such as pure water and sulfuric acid are supplied not into the external bath 20 but into the processing bath 10. Hereinbelow, the procedure of liquid exchange processing will be described paying attention to this difference.

In the following description, components similar to those of the substrate processing apparatus 1 according to the first preferred embodiment are designated by the same reference numerals. Since already described in the first preferred embodiment, those components given the same reference numerals will not be described in this preferred embodiment.

<2.1. Procedure of Liquid Exchange Processing>

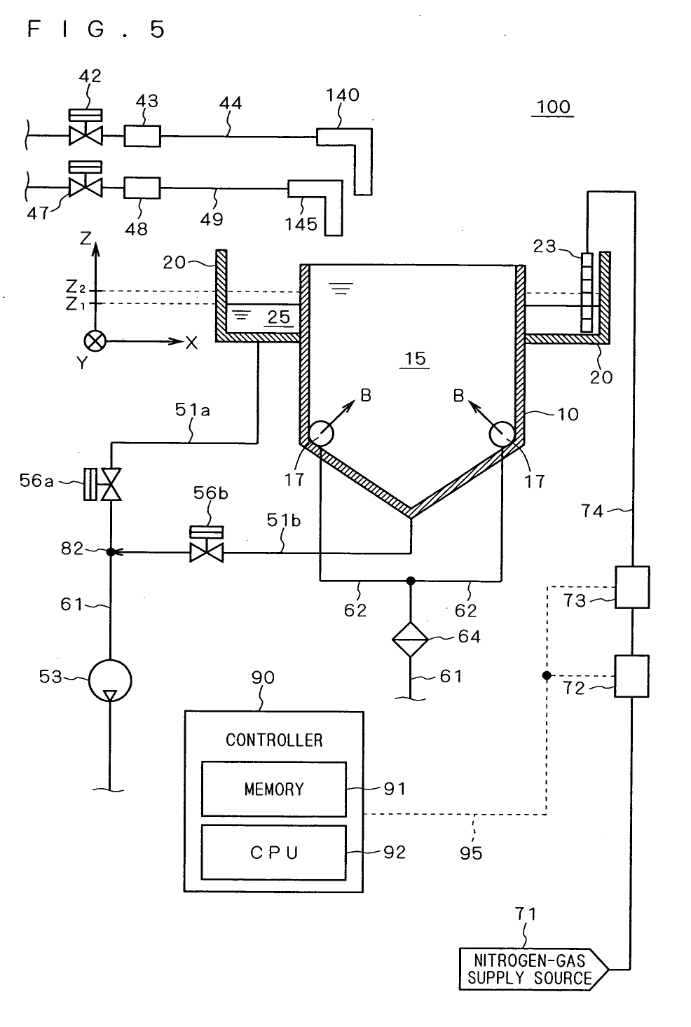

FIG. 5 is a diagram for explaining timing to start the circulation processing and timing to start the temperature control by the thermoregulator 63. Now, the procedure of the liquid exchange processing will be described mainly with reference to FIGS. 2, 4 and 5.

The following description is about the processing of exchanging pure water, which has been retained in the processing bath 10 before time t₁, for sulfuric acid. Before time t₁ in FIG. 2, the substrates W shall be moved up by the elevation mechanism 30 in the positive Z axis direction and delivered to a carrier robot (not shown). Further, sulfuric acid supplied into the processing bath 10 shall be of approximately room temperature.

In the liquid exchange processing, as in the first preferred embodiment, the pure water 15 retained in the processing bath 10 is discharged to the drainage 59 during time between t₁ and t₂ (processing-bath drainage), the pure water 25 collected in the external bath 20 is discharged to the drainage 59 during time between t₂ and t₃ (external-bath drainage), and pure water remaining in the supply pipes 62 is discharged to the drainage 59 during time between t₃ and t₄ (pipe drainage).

Then, at time t₄, sulfuric acid in the sulfuric-acid supply source 41 is supplied through the pipe 44 and from the supply nozzle 140 into the processing bath 10 in which the sulfuric acid is retained. The supply of sulfuric acid continues until time t₇ when the necessary amount of supply for substrate processing is completed.

Here, if the amount of sulfuric acid supplied from the supply nozzle 140 exceeds the maximum amount of storage in the processing bath 10, the excess amount of sulfuric acid overflows from the processing bath 10 and is collected in the external bath 20. Then, at time t₅ when it is determined from the detection value of the pressure sensor 73 that the level Z and the amount V of the sulfuric acid 25 retained in the external bath 20 reach Z1 (indicated by solid lines in FIG. 5) and V1, respectively, the circulation processing for circulating the sulfuric acid 25 from the external bath 20 to the processing bath 10 is started. Further, at time t₆ when it is determined that the level Z and the amount V of the sulfuric acid 25 retained in the external bath 20 reach Z2 (indicated by broken lines in FIG. 5) and V2, respectively, the temperature control by the thermoregulator 63 is started.

In this way, like the substrate processing apparatus 1 of the first preferred embodiment, the substrate processing apparatus 100 according to this preferred embodiment can start the temperature control while circulating sulfuric acid, before time t₇ when the supply of sulfuric acid is completed. This can speed up the start time of the temperature control and thus can shorten the time required for the liquid exchange processing.

Then, the liquid exchange processing is completed at time t₈ when the temperature of the sulfuric acid 15 retained in the processing bath 10 is increased to a temperature at which substrate processing becomes possible, by continuing the execution of the circulation processing.

Even after time t₈ when the substrate processing is started after the completion of the liquid exchange processing, the circulation processing is continued to be executed. Thus, sulfuric acid overflowing from the processing bath 10 is collected in and discharged from the external bath 20 and receives thermal energy transmitted from the thermoregulator 63 provided on the common pipe 61. This allows the sulfuric acid to be maintained at a predetermined temperature.

<2.2. Advantages of Substrate Processing Apparatus of Second Preferred Embodiment>

As so far described, like the substrate processing apparatus 1 of the first preferred embodiment, the substrate processing apparatus 100 according to the second preferred embodiment can start the circulation of sulfuric acid at time t₅, i.e., before time t₇ when the supply of sulfuric acid is completed, and can start the temperature control of sulfuric acid circulating through the common pipe 61 at time t₆. This can speed up the start time of the temperature control and thus can shorten the time required for the liquid exchange processing.

### 3. Third Preferred Embodiment

<3.1. Configuration of Substrate Processing Apparatus>

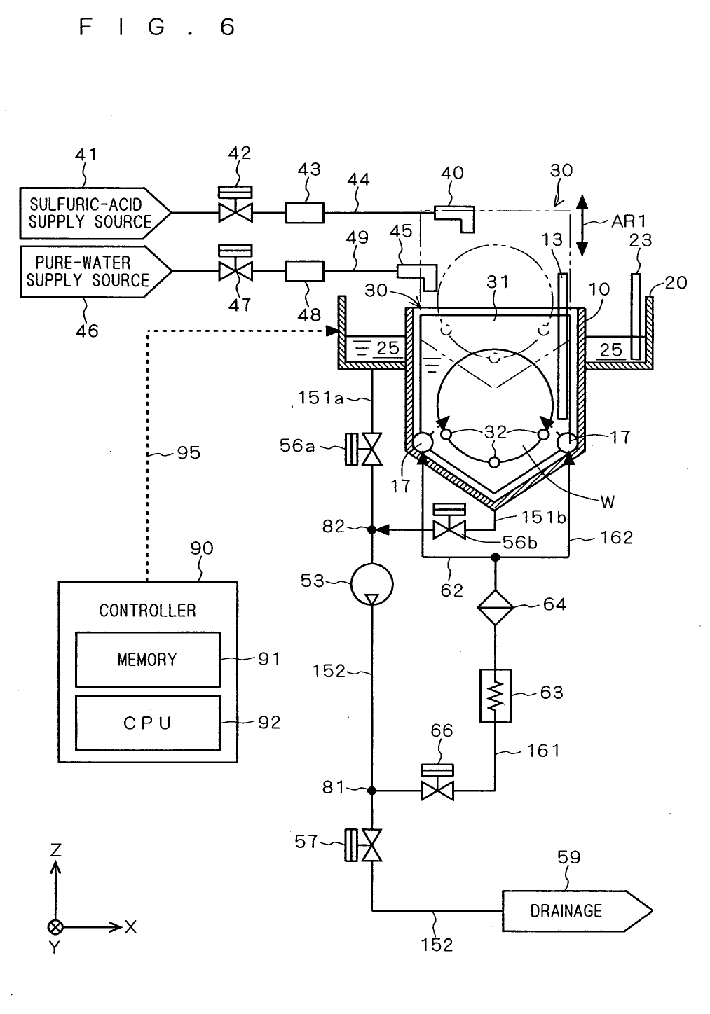

Next, a third preferred embodiment of the present invention will be described. FIG. 6 shows an example of the configuration of a substrate processing apparatus 200 according to the third preferred embodiment. The substrate processing apparatus 200 is a so-called “batch” substrate processing apparatus for processing a plurality of substrates at a time. As shown in FIG. 6, the substrate processing apparatus 200 mainly includes the processing bath 10, the external bath 20, pipes 151a, 151b, 152, 161 and 162 which are used to resupply processing liquids discharged from the processing bath 10 and the external bath 20 into the processing bath 10, the valves 42, 47, 56a, 56b, 57, and 66 which are provided on the corresponding pipes to determine passages of the processing liquids flowing through the pipes 151a, 151b, 152, 161, and 162. In the following description, components similar to those of the substrate processing apparatuses 1 and 100 according to the first and second preferred embodiments are designated by the same reference numerals.

The processing bath 10 is a reservoir for retaining a processing liquid. The processing bath 10 immerses a plurality of substrates W in a processing liquid retained therein so that the plurality of substrates W can be processed at a time. The processing bath 10 has the two processing-liquid nozzles (second suppliers) 17 provided near the bottom, so that processing liquids once discharged from the processing bath 10 and the external bath 20 are resupplied from the processing-liquid nozzles 17 into the processing bath 10.

Inside the processing bath 10, there is provided a level sensor (storage-amount detection sensor) 13 which detects the level of the processing liquid retained in the processing bath 10. Since the inner shape of the processing bath 10 is known, the amount of storage in the processing bath 10 can be determined by the level of the processing liquid. That is, there is a one-to-one correspondence between the amount and the level of the processing liquid retained in the processing bath 10. Accordingly, in this preferred embodiment, predetermined processing is performed based on the level of the processing liquid which is a detection result by the level sensor 13, or based on the amount of storage determined from the detection result by the level sensor 13.

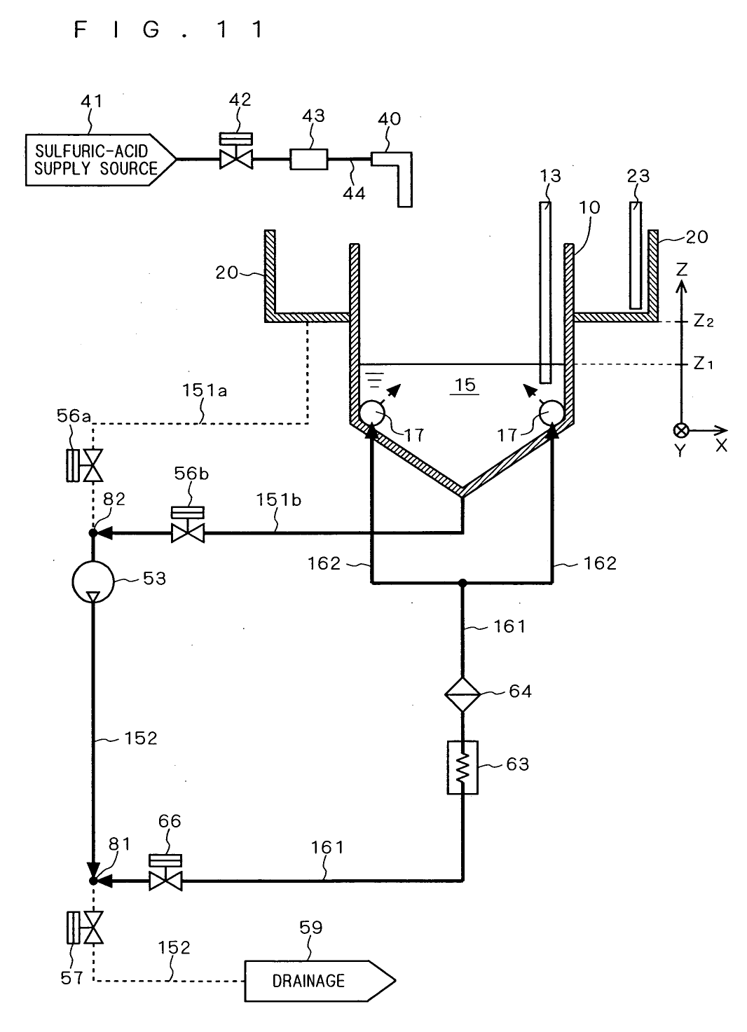

For example, when the level Z of the processing liquid retained in the processing bath 10 reaches Z1 as shown in FIG. 11 which will be described later, the circulation processing for resupplying the processing liquid discharged from the processing bath 10 into the processing bath 10 may be performed. Further, when the level Z reaches Z2, the temperature control by the thermoregulator 63 may be performed.

Above the processing bath 10, the supply nozzles (first suppliers) 40 and 45 are provided. As shown in FIG. 6, the supply nozzle 40 is communicated and connected to the sulfuric-acid supply source 41 via the valve 42, the flowmeter 43, and the pipe 44. The supply nozzle 45 is communicated and connected to the pure-water supply source 46 via the valve 47, the flowmeter 48, and the pipe 49. By controlling on and off of the valves 42 and 47, the supply nozzles 40 and 45 supply sulfuric acid and pure water, respectively, into the processing bath 10 from above.

The flowmeters 43 and 48, as shown in FIG. 6, are provided on the pipes 44 and 49, respectively. Those flowmeters 43 and 48 measure the flow rates of sulfuric acid supplied from the sulfuric-acid supply source 41 and pure water supplied from the pure-water supply source 46 per unit time, respectively. Thus, the amounts of sulfuric acid and pure water supplied into the processing bath 10 can be determined based on the detection values of the flowmeters 43 and 48.

The elevation mechanism 30 is a mechanism for immersing the substrates W in a processing liquid retained in the processing bath 10 and, as shown in FIG. 6, mainly includes the lifter 31 and the holding bars 32. The lifter 31 is moved up and down in the Z axis direction by a drive mechanism (not shown). The lifter 31 has the three holding bars 32 attached thereto and extending along the Y axis direction. The three holding bars 32 each have a plurality of holding grooves engraved thereon, and the substrates W are held in upright positions with their outer edges being inserted in the corresponding holding grooves.

Thus, the plurality of substrates W held by the three holding bars 32 are moved up and down by the lifter 31 between their positions immersed in the processing liquid and their positions to be delivered to a carrier robot (not shown).

On the outer top part of the processing bath 10, as shown in FIG. 6, the external bath 20 is provided to surround the outer edge of the processing bath 10. Thus, a processing liquid supplied into and overflowing from the processing bath 10 is collected in the external bath 20.

Inside the external bath 20, there is provided the level sensor (collection-amount detection sensor) 23 which detects the level of the processing liquid 25 collected in the external bath 20. Since the inner shape of the external bath 20 is known, there is a one-to-one correspondence between the amount and the level of the collected processing liquid. Accordingly, in this preferred embodiment, predetermined processing is performed based on the level of the processing liquid which is a detection result by the level sensor 23, or based on the amount of collection determined from the detection result by the level sensor 23.

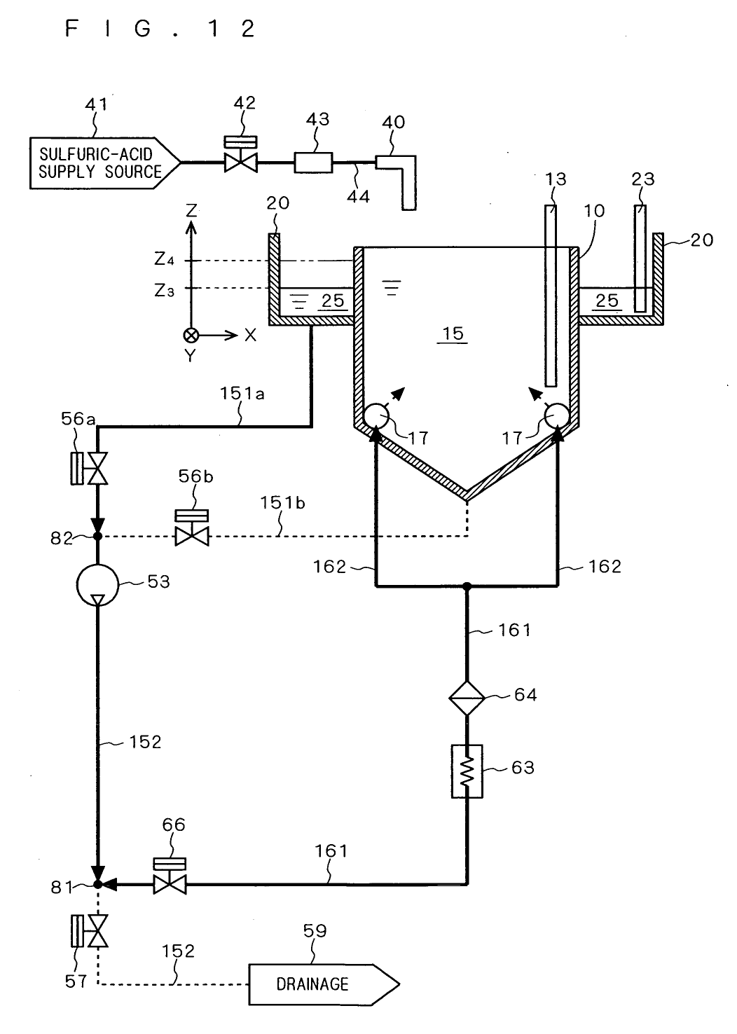

For example, when the level Z of the processing liquid collected in the external bath 20 reaches Z3 as shown in FIG. 12 which will be described later, circulation processing for supplying the processing liquid discharged from the external bath 20 into the processing bath 10 may be performed. When the level Z reaches Z4, processing for closing the valve 42 to stop the supply of sulfuric acid into the processing bath 10 may be performed.

Now, when a processing liquid used in substrate processing in the substrate processing apparatus 200 according to this preferred embodiment is discharged as a waste fluid, this used processing liquid is discharged to the drainage 59 which is provided outside the substrate processing apparatus 200 and used as a common facility in a semiconductor factory.

That is, as shown in FIG. 6, inside the external bath 20 is communicated to a branch discharge pipe (second discharge pipe) 151a which has the openable valve (second valve) 56a provided thereon. Inside the processing bath 10 is communicated to a branch discharge pipe (first discharge pipe) 151b which has the openable valve (first valve) 56b provided thereon. The branch discharge pipes 151a and 151b are communicated to a common discharge pipe 152 at the communication point 82. One end of the common discharge pipe 152, which is on the opposite side of the communication point 82, is communicated and connected to the drainage 59 via the pump 53 and the valve (fourth valve) 57.

Thus, driving the pump 53 as well as opening the valves 56a and 57 and closing the valve 56b and the valve 66 to be described later cause the processing liquid 25 collected in the external bath 20 to be discharged through the branch discharge pipe 151a and the common discharge pipe 152 to the drainage 59. On the other hand, driving the pump 53 as well as opening the valves 56b and 57 and closing the valves 56a and 66 cause the processing liquid retained in the processing bath 10 to be discharged through the branch discharge pipe 151b and the common discharge pipe 152 to the drainage 59.

The substrate processing apparatus 200 according to this preferred embodiment has also employed the structure of resupplying both the processing liquid retained in the processing bath 10 and the processing liquid 25 collected in the external bath 20 into the processing bath 10.

More specifically, as shown in FIG. 6, one ends of two branch supply pipes 162 each are communicated to a corresponding one of the processing-liquid nozzles (second suppliers) 17. The other ends of the branch supply pipes 162 are communicated to one end of a supply pipe 161. The supply pipe 161 has the openable valve (third valve) 66 provided thereon. The other end of the supply pipe 161 is communicated to the common discharge pipe 152 via the filter 64, the thermoregulator 63, and the valve 66. Here, the supply pipe 161 is communicated to the common discharge pipe 152 at the communication point 81 between the pump 53 and the valve 57 on the side closer to the drainage 59 than the point 82.

Thus, driving the pump 53 as well as opening the valves 56b and 66 and closing the valves 56a and 57 cause the processing liquid retained in the processing bath 10 to be resupplied into the processing bath 10. Further, driving the pump 53 as well as opening the valves 56a and 66 and closing the valves 56b and 57 cause the processing liquid 25 collected in the external bath 20 to be supplied into the processing bath 10.

In this way, the substrate processing apparatus 200 according to this preferred embodiment can perform two processing-liquid circulation processing: (1) the processing for resupplying a processing liquid discharged from the processing bath 10 into the processing bath 10; and (2) the processing for supplying a processing liquid discharged from the external bath 20 into the processing bath 10.

The filter 64, as shown in FIG. 6, is provided on the supply pipe 161 to remove particles or the like contained in a processing liquid circulating through the supply pipe 161. This allows the processing-liquid nozzles 17 to supply a processing liquid with no particles into the processing bath 10, even in the case of circulating a processing liquid simultaneously with the substrate processing in the processing bath 10.

The thermoregulator 63, as shown in FIG. 6, is provided on the supply pipe 161 between the filter 64 and the valve 66 to heat the processing liquid circulating through the supply pipe 161. That is, the thermoregulator 63 can control and increase the temperature of the processing liquid circulating through the supply pipe 161.

The controller 90, as shown in FIG. 6, includes the memory 91 that stores programs, variables, and the like, and the CPU 92 that exercises control according to programs stored in the memory 91. Thus, the CPU 92 exercises control of the opening and closing of the valves 42, 47, 56a, 56b, 57, and 66, control of the driving of the pump 53 and the thermoregulator 63, and other control according to programs stored in the memory 91.

<3.2. Procedure of Liquid Exchange Processing>

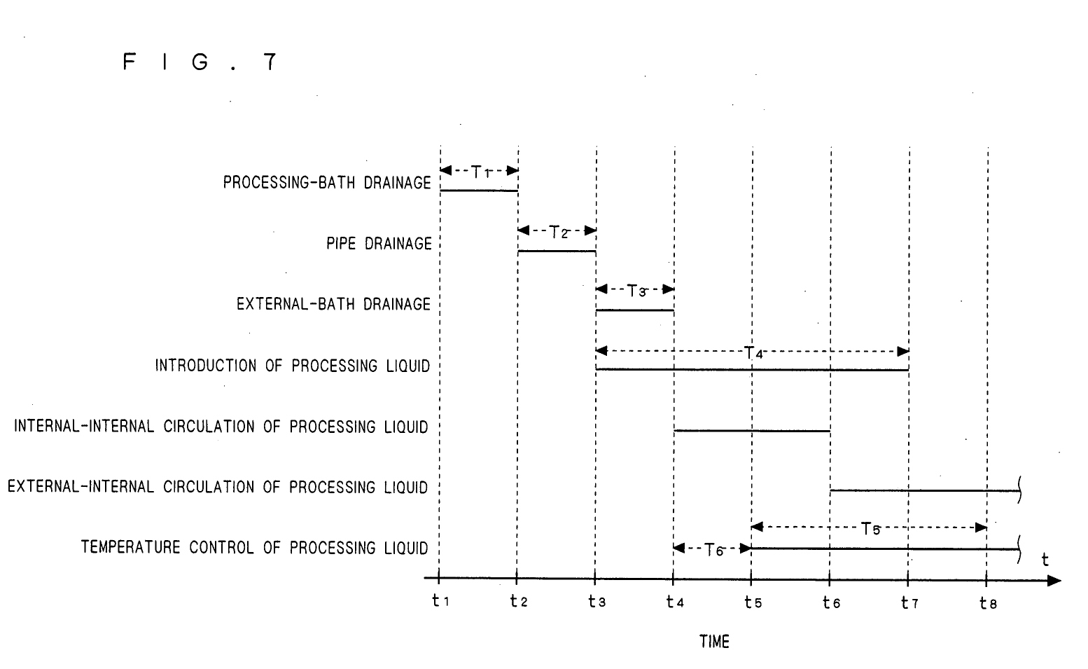

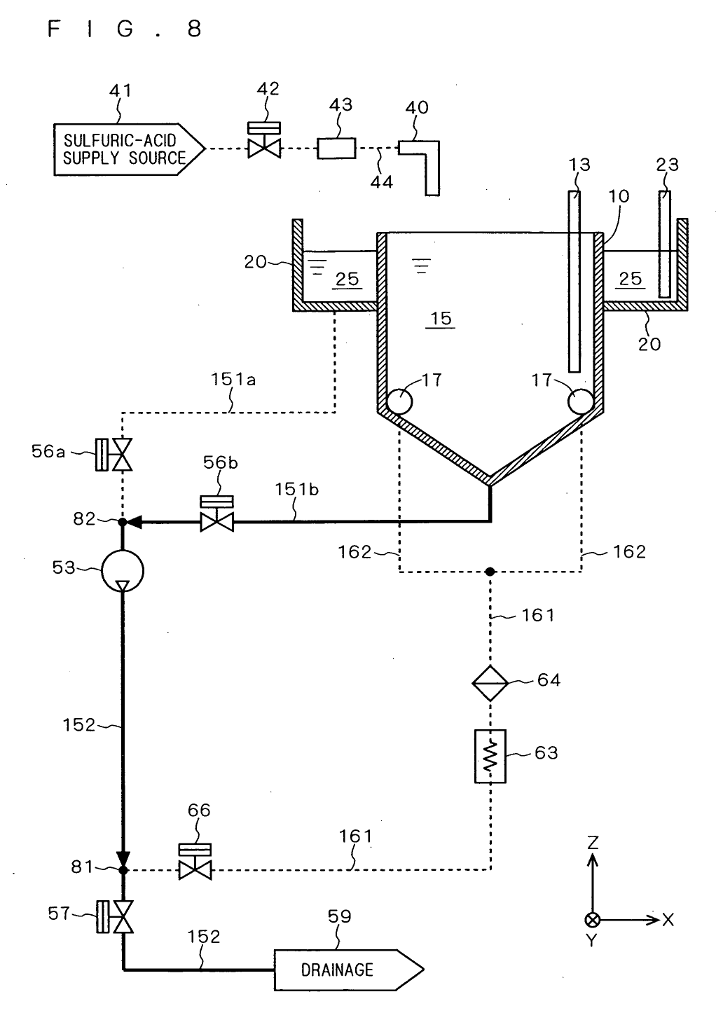

FIG. 7 is a timing chart for explaining the processing-liquid exchange processing according to this preferred embodiment. FIGS. 8 to 12 are diagrams for explaining passages of processing liquids in the liquid exchange processing. Now, the procedure of the liquid exchange processing according to this preferred embodiment will be described with reference to FIGS. 7 to 12.

For convenience of explanation, before time t₁ in FIG. 7, the substrates W shall be moved up by the elevation mechanism 30 in the positive Z axis direction and delivered to a carrier robot not shown. In FIGS. 8 to 12, the pipes shown by thick lines indicate the passage of processing liquids at each stage in the liquid exchange processing.

Although the following description is about the processing of exchanging pure water (H₂O), which has been retained in the processing bath 10 before time t₁, for sulfuric acid (H₂SO₄), the liquid exchange processing is not limited thereto. That is, processing liquids used before and after exchange may be any liquids other than pure water and sulfuric acid, respectively.

At time t₁, the pump 53 starts its operation, the valves 56b and 57 are opened, and the valves 56a and 66 are closed. Thereby, the pure water (first processing liquid) retained in the processing bath 10 is discharged by drive of the pump 53 through the branch discharge pipe 151b and the common discharge pipe 152 to the drainage 59 (see the thick lines in FIG. 8).

Then, pure water remaining in the processing bath 10, the branch discharge pipe 151b, and the common discharge pipe 152 is discharged on the side closer to the drainage 59 than the communication point 81 at least until a time lapse of T1 between t₁ and t₂. The time lapse of T₁ is a value that is determined according to the amount of pure water retained in the processing bath 10, the internal diameter and the length of the branch discharge pipe 151b, the discharge capability of the pump 53, and the like, and it is predetermined through experiments or the like.

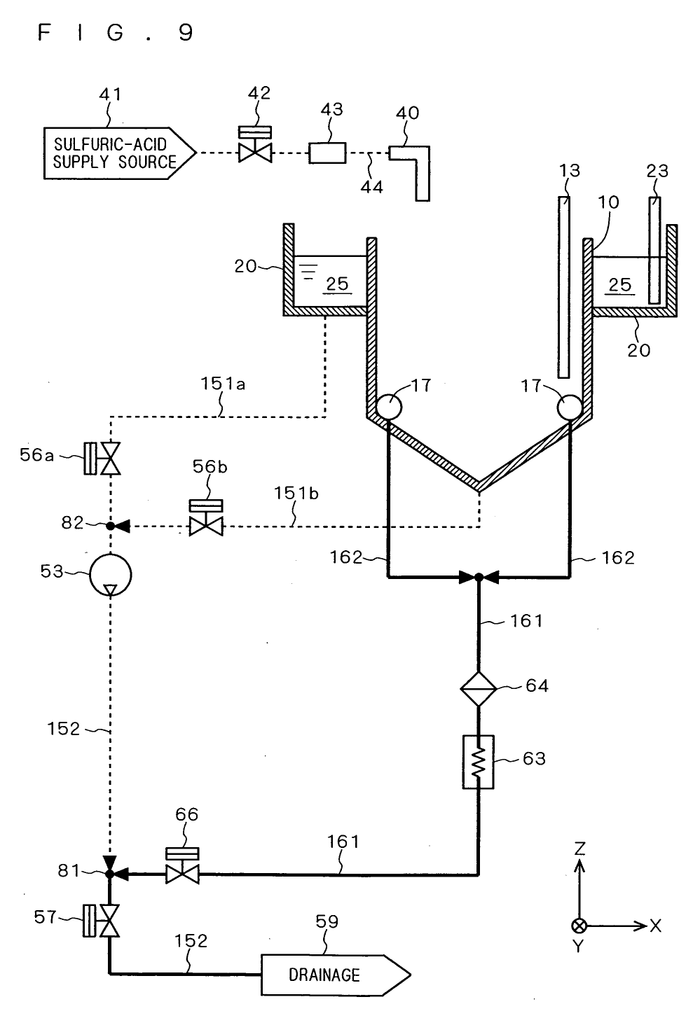

Then, at time t₂, with the valve 57 remaining open and the valve 56a remaining close, the pump 53 stops its operation, the valve 56b is closed, and the valve 66 is opened. Thereby, pure water remaining in the two branch supply pipes 162 and the supply pipe 161 is discharged under its own weight to the drainage 59 at least until a time lapse of T2 between t₂ and t₃ (see the thick lines in FIG. 9). The time lapse of T2 is a value that is determined according to the internal diameters and the lengths of the branch supply pipes 162 and the supply pipe 161, and the like, and it is predetermined through experiments or the like.

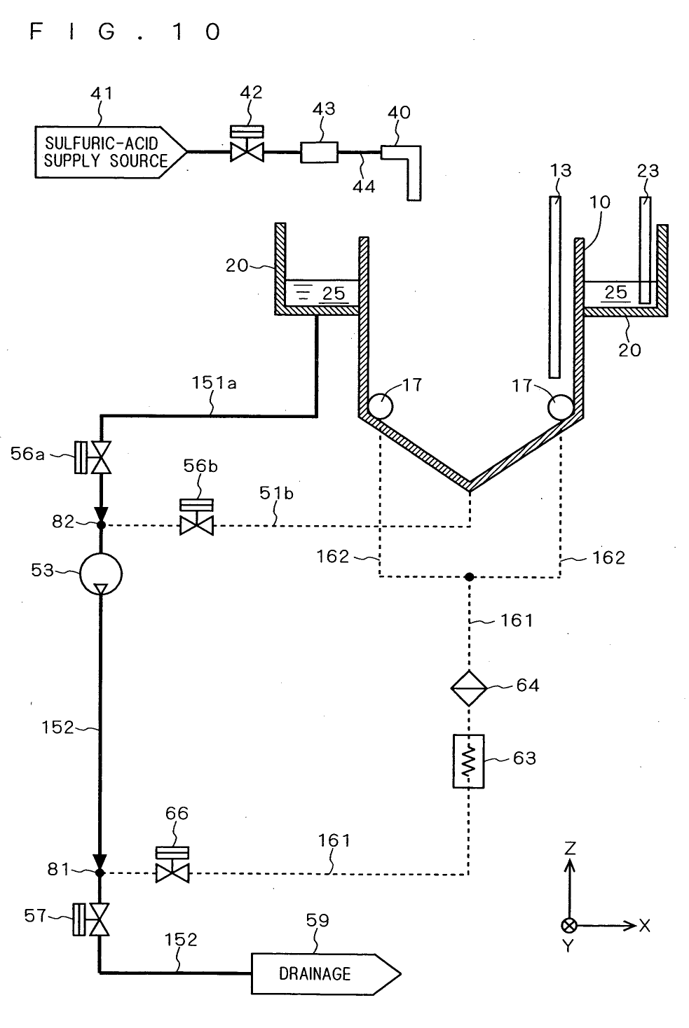

Then, at time t₃, with the valve 57 remaining open and the valve 56b remaining close, the pump 53 starts its operation, the valve 66 is closed, and the valve 56a is opened. Thereby, the pure water 25 collected in the external bath 20 is discharged by drive of the pump 53 through the branch discharge pipe 151a and the common discharge pipe 152 to the drainage 59 (see the thick lines in FIG. 10).

Then, pure water remaining in the external bath 20 and in the branch discharge pipe 151a is discharged on the side closer to the drainage 59 than the communication point 81 at least until a time lapse of T3 from t₃. The time lapse of T3 is a value that is determined according to the amount of pure water collected in the external bath 20, the internal diameter and the length of the branch discharge pipe 151a, the discharge capability of the pump 53, and the like, and it is predetermined through experiments or the like.

Also at time t₃, the processing of supplying sulfuric acid into the processing bath 10 is performed at the same time as the processing of discharging pure water from the external bath 20. More specifically, at time t₃, the valve 42 is opened so that sulfuric acid in the sulfuric-acid supply source 41 is supplied through the pipe 44 and from the supply nozzle 40 into the processing bath 10. This is the start of retention of sulfuric acid in the processing bath 10.

In this way, the processing of discharging pure water from the external bath 20 and the processing of retaining sulfuric acid in the processing bath 10 are concurrently performed at time t₃.

Then, at time t₄ when it is determined from the detection value of the level sensor 13 that the level Z of sulfuric acid retained in the processing bath 10 reaches Z1 (indicated by the solid lines in FIG. 11), the valves 56a and 57 are closed and the valves 56b and 66 are opened, with the pump 53 remaining in operation.

Thereby, sulfuric acid discharged from the processing bath 10 is resupplied by drive of the pump 53 through the branch discharge pipe 151b, the common discharge pipe 152, the supply pipe 161, and the two branch supply pipes 162 and from the processing-liquid nozzles 17 into the processing bath 10 (see the thick lines in FIG. 11). That is, first circulation processing (hereinafter referred to also as “internal-internal circulation processing) for circulating sulfuric acid from the processing bath 10 again into the processing bath 10 is started at time t₄.

Here, the valve 42 remains open even after the start of the internal-internal circulation processing, so that the processing bath 10 is continued to be supplied with sulfuric acid. The level Z1 of sulfuric acid, which is used as a trigger to start the internal-internal circulation processing, is predetermined through experiments or the like.

Then, at time t₅ which is after a time lapse of T6 from t₄ and when it is determined from the detection value of the level sensor 13 that the level Z of sulfuric acid retained in the processing bath 10 reaches Z2 (indicated by the broken lines in FIG. 11), the thermoregulator 63 starts its operation with the internal-internal circulation processing being continued.

Here, the valve 42 remains open even after the start of the temperature control, so that the processing bath 10 is continued to be supplied with sulfuric acid. Then, sulfuric acid overflowing from the processing bath 10 is collected in the external bath 20.

Then, at time t₆ when it is determined from the detection value of the level sensor 23 that the level Z of sulfuric acid collected in the external bath 20 reaches Z3 (indicated by the solid lines in FIG. 12), the valve 56b is closed and the valve 56a is opened with the pump 53 and the thermoregulator 63 remaining in operation and the valves 66 and 57 remaining open and close, respectively.

Thereby, sulfuric acid discharged from the external bath 20 is supplied by the driving energy of the pump 53 through the branch discharge pipe 151a, the common discharge pipe 152, the supply pipe 161, and the two branch supply pipes 162 and from the processing-liquid nozzles 17 into the processing bath 10 (see the thick lines in FIG. 12). That is, at time t₆, the internal-internal circulation processing is stopped and second circulation processing (hereinafter referred to also as “external-internal circulation processing”) for circulating sulfuric acid from the external bath 20 to the processing bath 10 is started.

Here, the valve 42 remains open even after the start of the external-internal circulation processing, so that the processing bath 10 is continued to be supplied with sulfuric acid. Further, the level Z of sulfuric acid, which is used as a trigger to start the external-internal circulation processing, is predetermined through experiments or the like.

Then, at time t₇ when it is determined from the detection value of the level sensor 23 that the level Z of sulfuric acid collected in the external bath 20 reaches Z4 (indicated by the broken lines in FIG. 12), the valve 42 is closed with the external-internal circulation processing being continued. This stops the supply of sulfuric acid from the supply nozzle 40 into the processing bath 10. On the other hand, the thermoregulator 63 remains in operation during the external-internal circulation processing. Then, at time t₈ when the temperature of sulfuric acid is increased to a temperature at which substrate processing becomes possible, the liquid exchange processing is completed.

Even after time t₈ when the substrate processing is started after the completion of the liquid exchange processing, the external-internal circulation processing is continued to be executed, and the temperature of sulfuric acid is controlled by the thermoregulator 63. This allows the sulfuric acid to be maintained at a predetermined temperature. If the processing liquid retained in the processing bath 10 is other than sulfuric acid, the processing liquid is maintained at a predetermined temperature at which appropriate substrate processing using the processing liquid becomes possible.

<3.3. Comparison of Liquid Exchange Procedure Between Third Preferred Embodiment and Conventional Techniques>

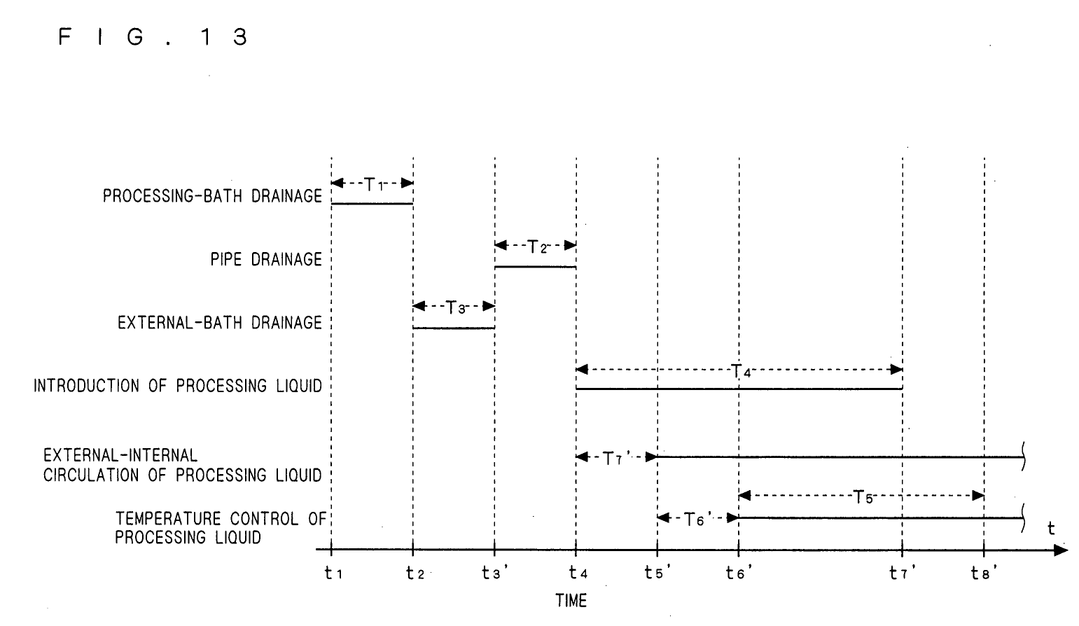

FIG. 13 is a timing chart for explaining conventional liquid exchange processing. We will now compare the liquid exchange processing according to this preferred embodiment with conventional one.

The following description is about the procedure of conventional liquid exchange processing performed by the substrate processing apparatus 200 according to this preferred embodiment. As in the liquid exchange processing according to this preferred embodiment, the processing of exchanging pure water for sulfuric acid will be described on the assumption that the processing bath 10 has retained pure water before time t₁ in FIG. 13.

In the conventional liquid exchange processing, firstly as in this preferred embodiment, the pure water 15 retained in the processing bath 10 is discharged to the drainage 59 during the time lapse of T1 between t₁ and t₂. Then, the pure water 25 collected in the external bath 20 is discharged to the drainage 59 during the time lapse of T3 between t₂ and t₃′. Then, pure water remaining in the two branch supply pipes 162 and the supply pipe 161 is discharged to the drainage 59 during the time lapse of T2 between t₃′ and t₄.

Then, the processing of supplying sulfuric acid into the processing bath 10 is performed at time t₄ when the processing of discharging pure water from the processing bath 10, the external bath 20, the two branch supply pipes 162, and the supply pipe 161 is completed. Then, the external-internal circulation processing is started at time t₅ which is after a time lapse of T7′ from t₄ and when it is determined from the detection value of the level sensor 23 that the level Z of sulfuric acid collected in the external bath 20 reaches Z3 (indicated by solid lines in FIG. 12). Then, the supply of sulfuric acid from the supply nozzle 40 into the processing bath 10 is stopped at time t₆′ which is after a time lapse of T6′ from time t₅ and when it is determined from the detection value of the level sensor 23 that the level Z of sulfuric acid collected in the external bath 20 reaches Z4 (indicated by broken lines in FIG. 12). On the other hand, the thermoregulator 63 remains in operation during the external-internal circulation processing. Then, at time t₈ when the temperature of sulfuric acid is increased to a temperature at which substrate processing becomes possible, the liquid exchange processing is completed.

Now, if the amount of sulfuric acid supplied from the sulfuric-acid supply source 41 and the amount of sulfuric acid supplied per unit time each are the same between the liquid exchange processing according to this preferred embodiment and the conventional liquid exchange processing, the time lapse of T4 to introduce sulfuric acid (processing liquid) and the time lapse of T5 to control the temperature of sulfuric acid (processing liquid) each are the same between the liquid exchange processing according to this preferred embodiment and the conventional one. Thus, if the drain time of T1 to discharge a processing liquid from the processing bath 10, the drain time of T2 to discharge processing liquids from the pipes 161 and 162, and the drain time of T3 to discharge a processing liquid from the external bath 20 each are the same between the liquid exchange processing according to this preferred embodiment and the conventional liquid exchange processing, a time ΔT that is the subtraction of time T0 required for the liquid exchange processing according to this preferred embodiment from time T0′ required for the conventional liquid exchange processing can be expressed by:

$$\begin{matrix}Δ T = T {0}^{′} - T 0 \\ = \{ T 1 + T 2 + T 3 + ( T {7}^{′} + T {6}^{′} ) + T 5 \} - \{ T 1 + T 2 + ( T 3 + T 6 ) + T 5 \} \\ = T 3 + ( T {7}^{′} - T 3 ) + ( T {6}^{′} - T 6 )\end{matrix}$$

Here, since the internal-internal circulation processing and the temperature control according to this preferred embodiment are started at the stages before the processing liquid overflows from the processing bath 10 to the external bath 20, the following inequalities hold: T7′>T3 and T6′>T6. That is, the liquid exchange processing according to this preferred embodiment can speed up the start time of the circulation of a processing liquid and the start time of the temperature control as compared with the conventional liquid exchange processing. Further, since as above described, the time lapse of T4 to introduce sulfuric acid (processing liquid) and the time lapse of T5 to control the temperature of sulfuric acid (processing liquid) each are the same between the liquid exchange processing according to this preferred embodiment and the conventional liquid exchange processing, the inequality ΔT>0 holds true. Accordingly, the liquid exchange processing according to this preferred embodiment requires a shorter processing time than the conventional one.

<3.4. Advantages of Substrate Processing Apparatus of Third Preferred Embodiment>

As so far described, the substrate processing apparatus 200 according to this preferred embodiment can perform the processing of discharging a processing liquid (e.g., pure water) collected in the external bath 20 and the processing of supplying a new processing liquid (e.g., sulfuric acid) into the processing bath 10 concurrently during the exchange of a processing liquid retained in the processing bath 10. Besides, the circulation processing (internal-internal circulation processing) and the temperature control by the thermoregulator 63 can be performed at the stages before a new processing liquid overflows from the processing bath 10 to the external bath 20.

In other words, the liquid exchange processing according to this preferred embodiment can speed up the start time of the circulation of a processing liquid and the start time of the temperature control as compared with the conventional one. Accordingly, it is possible to shorten the time required for the liquid exchange processing for supplying a new processing liquid into the processing bath 10 and controlling the liquid at a predetermined temperature.

### 4. Modifications

While the preferred embodiments of the present invention have been described so far, the present invention is not only limited to the above examples.

While in the first and second preferred embodiments, nitrogen gas is discharged from the gas discharger 23, the present invention is not limited thereto. For example, the gas discharged from the gas discharger 23 may be any gas including inert gases such as argon and helium that can maintain chemical stability in relation to the processing liquid 25 retained in the external bath 20.

Further, while the first and second preferred embodiments have described the processing of exchanging pure water, which has been retained in the processing bath 10 before time t₁, for sulfuric acid, the present invention is not limited thereto and is also applicable to the case of exchanging a processing liquid retained in the processing bath 10 from sulfuric acid to pure water. Further, processing liquids used before and after exchange may be other than pure water and sulfuric acid, respectively, and a new processing liquid to be supplied may for example be phosphoric acid (H₃PO₄).

Furthermore, while in the first and second preferred embodiments, sulfuric acid introduced from the sulfuric-acid supply source 41 is not preheated and of approximately room temperature, the present invention is not limited thereto. For example, sulfuric acid whose temperature is controlled to be higher than room temperature may be supplied into the external bath 20. In other words, this preferred embodiment can achieve the purpose of the present invention when a processing liquid of a lower temperature than an appropriate temperature for substrate processing is supplied into the processing bath 10 or the external bath 20.

While in the third preferred embodiment, the branch discharge pipes 151a and 151b and the common discharge pipe 152 are communicated and connected at the same communication point 82, the present invention is not limited thereto. For example, the branch discharge pipes 151a and 151b may be communicated to the common discharge pipe 152 at different positions.

Further, while in the third preferred embodiment, the level sensor 13 as a single sensor can detect a plurality of amounts of storage, the present invention is not limited thereto. For example, two sensors which are turned on when the level of a processing liquid reaches predetermined levels may be provided inside the processing bath 10. In this case, the internal-internal circulation processing may be started at time t₄ (cf. FIG. 7) when the detection value of one of the sensors transitions from OFF to ON, and then the thermoregulator 63 may start its operation to control the temperature of a circulating processing liquid at time t₅ when the detection value of the other one of the sensors transitions from OFF to ON. Similarly, instead of the level sensor 23, two sensors which are turned on when the level of a processing liquid reaches predetermined levels may be provided inside the external bath 20, and the timing to start the external-internal circulation processing and the timing to close the valve 42 may be determined using those sensors.

While the invention has been shown and described in detail, the foregoing description is in all aspects illustrative and not restrictive. It is therefore understood that numerous modifications and variations can be devised without departing from the scope of the invention.

What is claimed is:

1. A substrate processing apparatus for processing substrates, comprising:
a processing bath retaining a processing liquid;
an external bath provided outside said processing liquid to collect a processing liquid overflowing from said processing bath;
a pipe communicating and connecting said external bath and said processing bath;
a thermoregulator provided on said pipe to control a temperature of a processing liquid flowing through said pipe;
a circulator provided on said pipe to supply a processing liquid discharged from said external bath through said pipe into said processing bath;
a sensor detecting the amount of a processing liquid retained in said external bath; and
a controller supplying a processing liquid discharged from said external bath through said pipe into said processing bath using said circulator when said sensor detects a first value of the amount of a processing liquid retained in said external bath, and actuating said thermoregulator when said sensor detects a second value of the amount of the processing liquid that is greater than said first value.

2. The substrate processing apparatus according to claim 1, further comprising:
a processing-liquid supplier supplying a processing liquid into said external bath,
wherein said sensor detects the amount of a processing liquid supplied from said processing-liquid supplier into said external bath.

3. The substrate processing apparatus according to claim 1, further comprising:
a processing-liquid supplier supplying a processing liquid into said processing bath,
wherein said sensor detects the amount of a processing liquid overflowing from said processing bath to said external bath.

4. The substrate processing apparatus according to claim 2, wherein
said processing liquid includes a first processing liquid and a second processing liquid,
said substrate processing apparatus further comprising:
a first discharge pipe connected to said processing bath to discharge a first processing liquid retained in said processing bath; and
a second discharge pipe connected to said pipe to discharge a first processing liquid retained in said external bath through said pipe,
wherein said processing-liquid supplier supplies a second processing liquid after a first processing liquid is discharged from said first and second discharge pipes.

5. A substrate processing apparatus for processing substrates, comprising:
a processing bath retaining a processing liquid;
a first supplier supplying a processing liquid into said processing bath;
an external bath provided outside said processing bath to collect a processing liquid overflowing from said processing bath;
a first discharge pipe discharging a processing liquid retained in said processing bath;
a first valve provided on said first discharge pipe;
a second discharge pipe discharging a processing liquid retained in said external bath;
a second valve provided on said second discharge pipe;
a common discharge pipe connected to said first and second discharge pipes to discharge a processing liquid discharged through said first and second discharge pipes;
a second supplier supplying a processing liquid discharged through said first and second discharge pipes into said processing bath;
a supply pipe connected to said common discharge pipe and said second supplier;
a third valve provided on said supply pipe;
a thermoregulator provided on said supply pipe to control a temperature of a processing liquid circulating through said supply pipe;
a fourth valve provided on said common discharge pipe and downstream of a point where said supply pipe is connected; and
a controller controlling supply of a processing liquid from said first supplier and opening and closing of said first to fourth valves,
said controller opening said first, third, and fourth valves to discharge a first processing liquid retained in said processing bath through said first discharge pipe and said common discharge pipe and to discharge a first processing liquid remaining in said supply pipe through said supply pipe and said common discharge pipe,
said controller, while causing said first supplier to supply a second processing liquid into said processing bath, opening said second valve to discharge a first processing liquid retained in said external bath through said second discharge pipe and said common discharge pipe,
said controller, while causing said first supplier to supply a second processing liquid into said processing bath, opening said first and third valves to perform first circulation processing for circulating a second processing liquid retained in said processing bath from said second supplier to said processing bath through said first discharge pipe, said common discharge pipe, and said supply pipe, and
said controller stopping said first circulation processing according to the amount of a second processing liquid collected in said external bath, and while causing said first supplier to supply a second processing liquid into said processing bath, opening said second and third valves to perform second circulation processing for circulating a second processing liquid collected in said external bath from said second supplier to said processing bath through said second discharge pipe, said common discharge pipe, and said supply pipe.

6. The substrate processing apparatus according to claim 5, wherein
said controller starts said first circulation processing and starts to operate said thermoregulator according to the amount of a second processing liquid retained in said processing bath.

7. The substrate processing apparatus according to claim 5, wherein
said controller starts to operate said thermoregulator after start of said first circulation processing.

8. The substrate processing apparatus according to claim 5, further comprising:
a collection-amount detection sensor detecting the amount of a second processing liquid collected in said external bath.

9. The substrate processing apparatus according to claim 6, further comprising:
a storage-amount detection sensor detecting the amount of a second processing liquid retained in said processing bath.
